(19) United States
(12) Patent Application Publication
(10) Pub. No.: US 2025/0234452 A1
(43) Pub. Date: Jul. 17, 2025

(54) MODULE-LEVEL THERMAL MANAGEMENT MECHANISM

(71) Applicant: Micron Technology, Inc., Boise, ID (US)

(72) Inventors: Mark A. Tverdy, Boise, ID (US); Kaleb A. Wilson, Caldwell, ID (US); Bradley R. Bitz, Boise, ID (US); Amy R. Griffin, Boise, ID (US)

(21) Appl. No.: 19/007,414

(22) Filed: Dec. 31, 2024

Related U.S. Application Data
(60) Provisional application No. 63/621,219, filed on Jan. 16, 2024.

(51) Int. Cl. H05K 1/02; H05K 9/00

(52) U.S. Cl. CPC H05K 1/0204; H05K 1/0215; H05K 9/0024; H05K 2201/066; H05K 2201/0707; H05K 2201/10159; H05K 2201/10371; H05K 2201/10522

(57) ABSTRACT

Methods and apparatuses related to printed circuit board assemblies having one or more thermally conductive posts used to improve cooling capacity are disclosed. The thermally conductive posts may be thermally coupled to one or more components mounted on a printed circuit board. Moreover, the thermally conductive posts may be configured to disrupt a flow of coolant over the printed circuit board assemblies.

### CROSS-REFERENCE TO RELATED APPLICATION(S)

The present application claims priority to U.S. Provisional Patent Application No. 63/621,219, filed Jan. 16, 2024, the disclosure of which is incorporated herein by reference in its entirety.

### TECHNICAL FIELD

The present technology is directed to apparatuses, and in particular to an electrical apparatus with module-level thermal management mechanism and methods of manufacturing the same.

### BACKGROUND

The trend in modern electronics is to manufacture electronic apparatuses (e.g., a processor, memory system, circuit board, and/or other electronic apparatuses) to be smaller and faster with both higher component densities (e.g., multiple memory devices) and greater capabilities (e.g., power management operations). For example, modern Printed Circuit Board (PCB) substrates can include a high density of memory devices and can include Power Management Integrated Circuits (PMICs), inductors, regulators, and many other components to further expand circuit board utility.

While these and similar technological advancements can have great utility in a wide variety of industries and technological sectors, they can often introduce new challenges. For example, PCB substrates combined with a higher capacity/performance components can necessitate improved thermal management capabilities to accommodate expanded functionality.

### BRIEF DESCRIPTION OF THE DRAWINGS

FIG. 1 is a perspective view of a first example apparatus in accordance with an embodiment of the present technology.

FIG. 2 is a top view of a second example apparatus in accordance with an embodiment of the present technology.

FIG. 3 is a cross-sectional view taken along a dashed line A-A of FIG. 2 of the second example apparatus in accordance with an embodiment of the present technology.

FIGS. 4A-4B are various views of a third example apparatus in accordance with an embodiment of the present technology.

FIGS. 5A-5B are various views of a fourth example apparatus in accordance with an embodiment of the present technology.

FIG. 6 is a flow diagram illustrating an example method of manufacturing an apparatus in accordance with an embodiment of the present technology.

FIG. 7 is a schematic view of a system that includes an apparatus in accordance with an embodiment of the present technology.

### DETAILED DESCRIPTION

The disclosed technology provides improvements in thermal dissipation using a module-level thermal management mechanism. For example, a Printed Circuit Board (PCB) substrate can include the module-level thermal management mechanism, such as one or more thermally conductive posts, at both the PCB and component levels. Improved thermal dissipation can reduce or prevent loss of integrity or operability disruption of corresponding circuit modules (e.g., Dual In-Line Memory Modules (DIMMs)), such as ones including higher density memories, Power Management Integrated Circuits (PMICs), or other components. For the purposes of the present technology, a PCB substrate combined with one or more components can be referred to as a Printed Circuit Board Assembly (PCBA).

The disclosed technology provides an electrical apparatus with the module-level thermal management mechanism, such as the PCBA including thermally conductive posts. The module-level thermal management mechanism can be configured to increase heat-removal paths and disrupt airflow passing over the PCBA. The disrupted airflow can increase thermal transmission (e.g., compared to laminar airflow) away from the heat-generating components, thereby providing improved cooling capacity of the PCBA. Further, the thermally conductive posts can be configured to provide a planar mounting interface for a label or heat spreader. Moreover, the thermally conductive posts can function as locating pins for attachment of mechanical parts and provide increased structural integrity (e.g., mechanical stiffness) to the PCBA. In some embodiments, the thermally conductive posts can be leveraged with other components (e.g., a non-conductive label connected to a heat sink connected to ground) to function as an electromagnetic interference (EMI) shield or a different type of shield.

In the following description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with semiconductor devices are not shown, or are not described in detail, to avoid obscuring other aspects of the technology. In general, it should be understood that various other devices, systems, and methods in addition to those specific embodiments disclosed herein may be within the scope of the present technology.

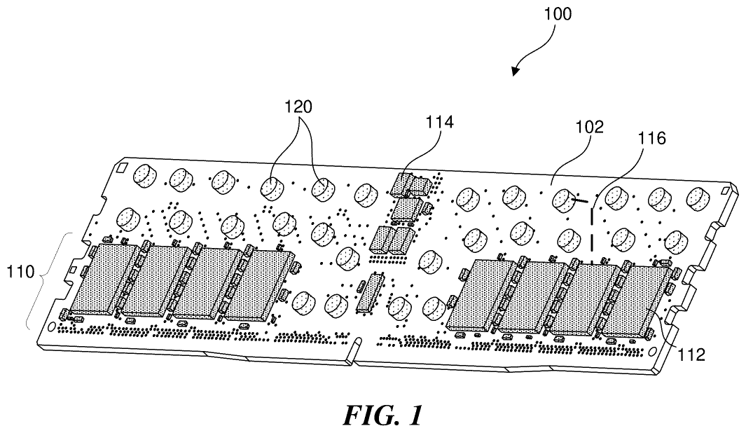

FIG. 1 is a perspective view of a first example apparatus 100 (e.g., a DIMM) in accordance with an embodiment of the present technology. The apparatus 100 can include a substrate, such as a PCB substrate 102 with one or more components 110 mounted thereon to form a PCBA. For example, the apparatus 100 can have passive and/or active circuit components. In some embodiments, the apparatus 100 can include one or more memory circuits 112 (e.g., Dynamic Random-Access Memory (DRAM) chips) and/or board-level power management circuits 114 (e.g., PMIC).

As the technology improves to increase the performance of electronic devices and/or reduce the size of such devices, the amount of data processing and the corresponding power consumption is rapidly increasing for a given area/space within the devices. As an illustrative example, some conventional memory modules (e.g., DIMMs) are now including onboard PMICs to account for and manage the increased power consumed by the overall module. However, such increased power consumption has further led to increase in the thermal energy generated and retained at the conventional modules and the circuits thereon.

Embodiments of the present technology includes one or more thermally conductive posts 120 to form a module-level thermal management mechanism. The one or more thermally conductive posts 120 can be configured to increase heat-removal paths and disrupt airflow passing over the PCBA. The thermally conductive posts 120 can include thermally-conductive material, such as metallic material, for (1) drawing heat away from the components 110 and (2) dissipating the heat out to the surrounding environment. In some embodiments, the thermally conductive posts 120 can be coupled to the components 110 using thermally-conductive paths 116, such as metallic traces or grounding planes, to form a thermal-circuit configured to facilitate the removal of the thermal energy.

The thermally conductive posts 120 can have a predetermined height above a surface of the PCB substrate 102. The predetermined height can be equal to or greater than that of the electrical components 110. Accordingly, the top surfaces of the thermally conductive posts 120 can be coincident with a lateral plane that is coincident with or extends over the top portions of the circuit components 110.

Further, the thermally conductive posts 120 can have a cross-sectional shape configured to facilitate the heat dissipation according to one or more environmental conditions (e.g., a known direction or intensity of air flow). For the illustrated example, the thermally conductive posts 120 are shown as having cylindrical shapes with a circular cross-sectional shape. However, it is understood that the cross-sectional shape can be different, such as a polygonal shape, a non-symmetrical shape, an oval, etc.

The thermally conductive posts 120 and/or the thermally-conductive paths 116 can be electrically isolated from the components 110. Accordingly, the thermally conductive posts 120 and/or the thermally-conductive paths 116 can be configured to transfer the thermal energy away from the circuit components 110 without interacting with the signals and/or other electrical connections to/from the circuit components 110. In other embodiments, the thermally conductive posts 120 and/or the thermally-conductive paths 116 can be electrically connected to one or more signals or voltage levels, such as an electrical ground. Further, as described in more detail below, the thermally conductive posts 120 and/or the thermally-conductive paths 116 can be electrically and/or physically connected to one or more protective structures, such as an EMI shield.

The thermally conductive posts 120 can be arranged on the PCB substrate 102 according to a targeted arrangement. For the (first) example arrangement illustrated in FIG. 1, the thermally conductive posts 120 can be located (1) on a top portion of the DIMM opposite board connectors on a bottom portion across the memory chips and (2) between groupings of the memory chips, such as in the middle portion of the PCB. In some embodiments, the thermally conductive posts 120 can be arranged according to a linear pattern, such as for rows and columns. Additionally, or alternatively, the thermally conductive posts 120 can be located offset from other reference locations or sub arrangements (e.g., offset rows/columns).

The arrangement of the thermally conductive posts 120 can be computed or designed to increase or maximize heat dissipation. For example, a manufacturer, a designer, a customer, or the like can use a computer model to estimate the heat dissipation rates for different placement locations of the thermally conductive posts 120. The computer model can use as inputs (1) estimated thermal energy output of the components 110 according to one or more intended operating states, (2) locations of the components 110 that generate at least a threshold amount of heat, and/or (3) environmental conditions, such as expected space above the thermally conductive posts 120 (e.g., according to DIMM slot separation distance) and/or anticipated airflow.

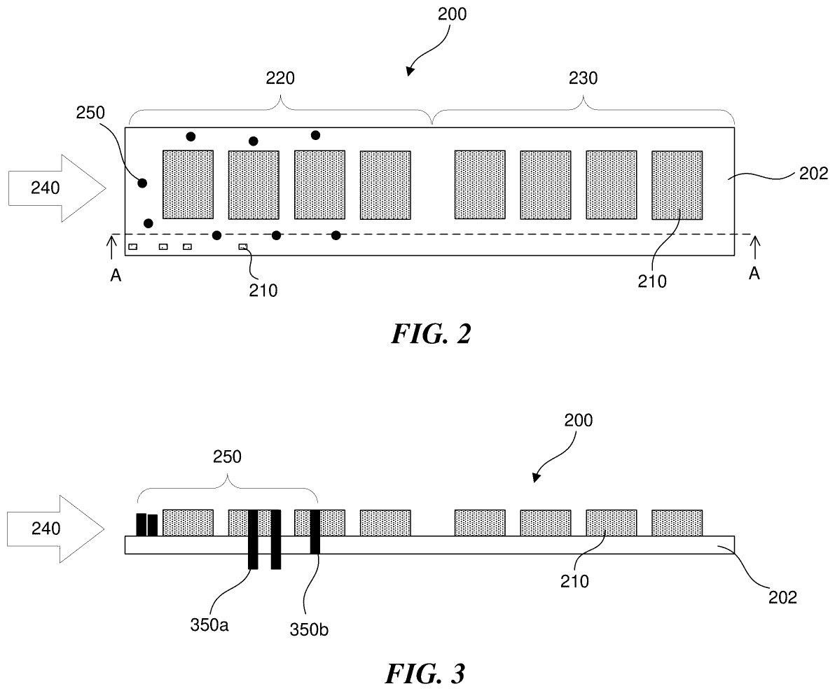

FIG. 2 is a top view of a second example apparatus 200 in accordance with an embodiment of the present technology. The second apparatus 200 can include structures similar to those of the first apparatus 100 of FIG. 1. For example, the apparatus 200 can include a PCB substrate 202 with one or more components 210 mounted thereon to form a PCBA. The apparatus 200 can further include one or more thermally conductive posts 250. FIG. 2 illustrates the apparatus 200 having a different arrangement of the thermally conductive posts 250 than the apparatus 100.

In some embodiments, the apparatus (e.g., the DIMM) can operate in an environment having a coolant (e.g., air) flowing along a designated direction. Accordingly, the apparatus can have an inlet portion 220 and an outlet portion 230 that extends generally parallel to a flow direction 240. For the example, illustrated in FIG. 2, the DIMM can be configured to be oriented in the operating environment where the length of the PCB substrate 202 is parallel to the flow direction 240. For such arrangement, the PCBA can be configured to have a first end closest to the source of the air flow designated as the inlet portion 220 and a second end opposite the first end designated as the outlet portion 230.

In illustrating the different arrangement of the thermally conductive posts 250, the second apparatus 200 can have a substantial number (e.g., more than half to all) of the posts located closer to the inlet portion 220 than the outlet portion 230. Further, the apparatus 200 can include the thermally conductive posts 250 above and/or below the memory chips. Moreover, the apparatus 200 can include one or more of the thermally conductive posts 250 located between a lateral peripheral edge of the PCB substrate 202 (e.g., at the inlet portion 220) and the components 110, such as for encountering the incoming coolant before and/or after the components.

The arrangement of the thermally conductive posts 250 can be designed to increase the rate of heat dissipation into the surrounding environment. In some embodiments, the arrangement can be configured to create disruptions in the flow of the coolant to increase the dissipation rate. In other words, the thermally conductive posts 250 can be arranged to increase the transfer duration between a mass of the coolant and the components 210 and/or cause the coolant to deviate from a laminate flow over the components 210 into spaces between the components 210. In comparison to the laminate flow that would otherwise occur, the thermally conductive posts 250 can be arranged to disrupt the coolant flow in a way that increases the heat dissipation away from the thermally conductive posts 250 and thus the thermally coupled components 210. Such arrangement of the thermally conductive posts 250 can be designed using a computer model that represents the thermal transfer and coolant flow relative to structures.

FIG. 3 is a cross-sectional view taken along a dashed line A-A of FIG. 2 of the second example apparatus 200 in accordance with an embodiment of the present technology. In some embodiments, the thermally conductive posts 250 can include flush mounted posts 350a, through posts 350b, or a variety of both. The flush mounted posts 350a can each have bottom portions thereof extending through a thickness of the PCB substrate 202 and coplanar with a bottom surface thereof. The through posts 350b can have bottom portions thereof extending past the bottom surface of the PCB substrate 202. The thermally conductive posts 250 can include other embodiments, such as (1) ones having bottom portions of the thermally conductive posts 250 attached to or over a top surface of the PCB substrate 202 or (2) ones having the bottom portions partially embedded in the thickness (e.g., located between the top surface and the bottom surface) of the PCB substrate 202.

The thermally conductive posts 250 can be cylindrical, cuboidal, spherical, conical, pyramidal, or any other shape. Furthermore, the thermally conductive posts 250 can be pins, ribs, dimples, or any other configuration that disrupts airflow and disperses heat into the surrounding environment (e.g., the flowing coolant). The thermally conductive posts 350 can be metal but can also be any non-ferrous or non-metallic material having thermally conductive characteristics.

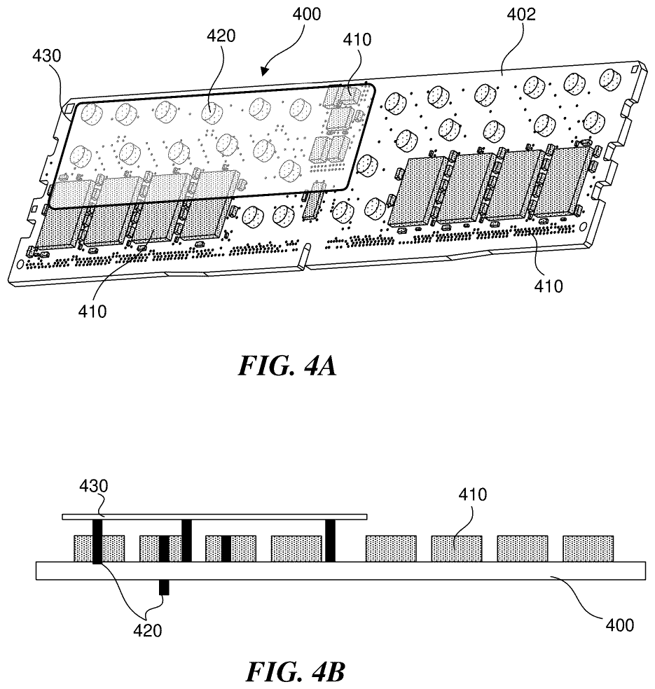

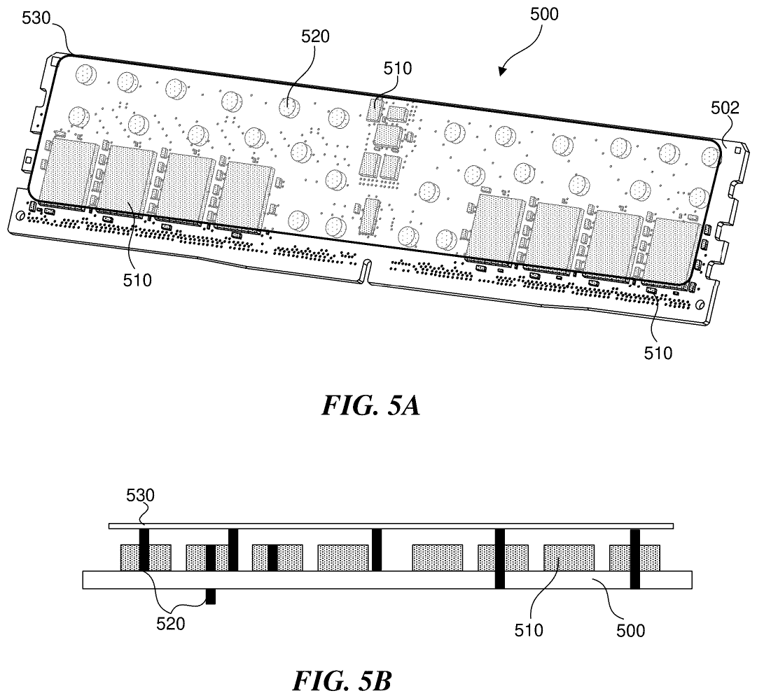

The thermally conductive posts 350/250 can be positioned so as to provide a mounting position for a label, heat spreader, or other components, as discussed below in FIGS. 4A-4B and FIGS. 5A-5B. In some embodiments, the thermally conductive posts 350/250 can be positioned so as to mitigate warpage of the PCB substrate during manufacturing. For example, the thermally conductive posts 350/250 can be positioned so as to create a uniform coefficient of thermal expansion across the PCB substrate during the manufacturing process.

FIGS. 4A-4B are various views of a third example apparatus 400 in accordance with an embodiment of the present technology. FIG. 4A is a schematic perspective view of the third apparatus 400, and FIG. 4B is a side view of the third apparatus 400 focusing on a select set of structures. Referring now to FIGS. 4A and 4B together, the third apparatus 400 can include structures similar to those of the first apparatus 100 of FIG. 1 and/or the second apparatus 200 of FIG. 2. For example, the third apparatus 400 can include a PCB substrate 402 with one or more components 410 mounted thereon to form a PCBA. The apparatus 400 can further include one or more thermally conductive posts 420. In some embodiments, the thermally conductive posts 420 can have any of the characteristics previously discussed in FIGS. 1-3, such as the different post arrangements and/or mounting level of the posts.

The thermally conductive posts 420 can be configured to provide a planar mounting interface for a first planar cover 430 (e.g., a label) that extends partially across a length of the PCB substrate 402. The planar cover 430 can be conductive or non-conductive. In some embodiments, the planar cover 430 is a non-conductive label having text or images thereon (e.g., manufacturer information, part number, or the like) or a protective shield. The planar cover 430 can be above and separated from top portions of one or more of the components 410 (e.g., memory chips, PMIC, or the like). In other embodiments, the planar cover 430 can be attached to, and/or directly thermally coupled (via, e.g., a thermally conductive adhesive or paste) to the top portions of or more of the components 410.

FIGS. 5A-5B are various views of a fourth example apparatus 500 in accordance with an embodiment of the present technology. FIG. 5A is a schematic perspective view of the fourth apparatus 500, and FIG. 5B is a side view of the fourth apparatus 500 focusing on a select set of structures. Referring now to FIGS. 5A and 5B together, the fourth apparatus 500 can include structures similar to those of the first apparatus 100 of FIG. 1, the second apparatus 200 of FIG. 2, and/or the third apparatus 300 of FIG. 4A. For example, the fourth apparatus 500 can include a PCB substrate 502 with one or more components 510 mounted thereon to form a PCBA. In some embodiments, the thermally conductive posts 520 can have any of the characteristics previously discussed in FIGS. 1-4B, such as the different post arrangements and/or mounting level of the posts.

The one or more thermally conductive posts 520 can be configured to provide a planar mounting interface for a second planar cover 530 that extends a majority of the length of the PCB substrate 502. For example, the second planar cover 530 can include thermally and/or electrically conductive material, such as for an EMI shield or a heat spreader. The second planar cover 530 can be above and separated from top portions of one or more of the components 510 (e.g., memory chips, PMIC, or the like). In other embodiments, the second planar cover 530 can be attached to, contact, and/or directly thermally connected (via, e.g., thermal adhesive or other thermally conductive material) to the top portions of or more of the components 510.

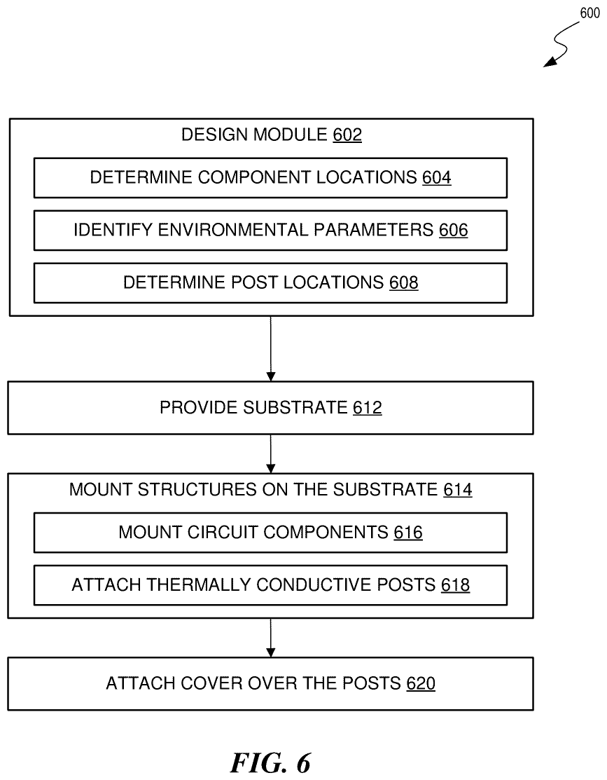

FIG. 6 is a flow diagram illustrating an example method 600 of manufacturing an apparatus in accordance with an embodiment of the present technology. The method 600 can be for manufacturing one or more of the apparatus described above (e.g., the apparatus 200 of FIG. 2, 400 of FIG. 4A, and/or 500 of FIG. 5A). For example, the method 600 can be for manufacturing a device, such as a DIMM, having the module-level thermal management mechanism (e.g., thermally conductive posts).

At block 602, the method 600 can include designing the apparatus, such as the module (e.g., DIMM). In designing a module, a computing system can identify (1) circuits and corresponding components (e.g., the components 110 of FIG. 1 or the like), (2) electrical connections (e.g., traces) between the components, and (3) thermally conductive posts (e.g., the thermally conductive posts 120 of FIG. 1 or the like) on a PCB. The computing system can identify the circuit components, the connections, and the type/number of posts according to one or more operating parameters, such as the targeted performance, the operating environment, and/or likely outputs under targeted load conditions. Moreover, the computing system can compute the locations of the components, the connections, and the posts on the PCB.

As an illustrative example of the module design, at block 604, the method 600 can include determining component locations, such as for the components 110 or the like. The components can be arranged according to one or more operating parameters, such as the physical space requirement and/or the targeted operating parameters. Also, the components can be arranged according to one or more industry standards.

At block 606, the method 600 can include identifying environmental parameters for the module. For example, a downstream customer or an intended operating environment (e.g., enterprise or server application, laptop usage, Artificial Intelligence module application, etc.) can be used to identify thermally-related parameters. For example, the identified environmental parameters can include spacing between the module and adjacent structures, targeted workload for the module, flow rate of any coolant, and/or the like.

At block 608, the method 600 can include determining post locations, such as for the thermally conductive posts 120 or the like. For example, the computing system can use one or more models, such as for estimating thermal transfer to coolant/surrounding environment, heat generation under workload, airflow pattern, or the like to estimate the heat generation of the component and the heat dissipation of the posts. The computing system can further test multiple candidate post locations and select the locations having the highest estimated thermal dissipation rate.

Once the module design is complete, the method 600 can include providing the substrate as illustrated at block 612. For example, the method 600 can include obtaining a PCB having the traces and mounting locations that correspond to the completed design. Moreover, providing the substrate can include preparing the PCB for surface mount. Alternatively, the PCB can be provided by manufacturing the PCB or one or more portions thereof (e.g., surface connections, vias, etc.) according to the completed design.

At block 614, the method 600 can include mounting structures, such as the components 110, the thermally conductive posts 120, and/or the like, on the provided substrate. Block 614 can correspond to a surface mounting process for mounting one or more chips, passive components, thermally conductive posts, etc. on the PCB. For example, at block 616, the method 600 can include mounting the components 110 or the like on the PCB. Likewise, at block 618, the method 600 can include attaching the thermally conductive posts 120 or the like on the PCB. The posts can be flush mounted, protruding through the PCB, and/or partially embedded into the PCB as described above.

At block 620, the method 600 can include attaching a cover (e.g., the first planar cover 430 of FIG. 4A and/or the second planar cover 530 of FIG. A) over the posts. For example, a label and/or a shield (e.g., EMI shield) can be attached onto top portions of the thermally conductive posts, top portions of the components, or both as described above.

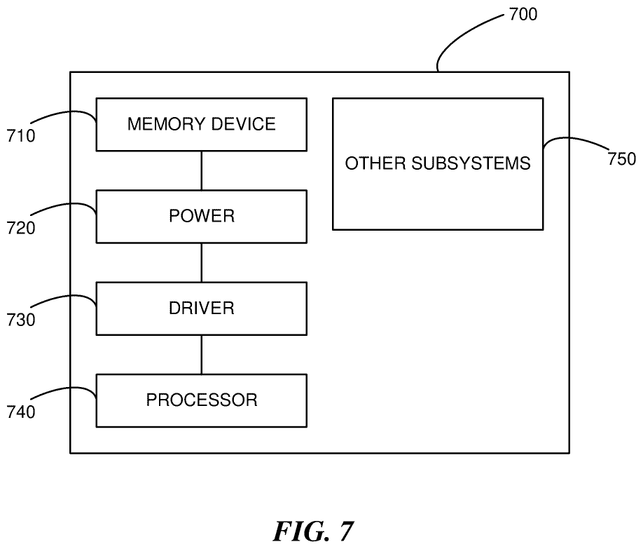

FIG. 7 is a schematic view of a system that includes an apparatus in accordance with an embodiment of the present technology. Any one of the foregoing apparatuses (e.g., memory devices) described above with reference to FIGS. 1-6 can be incorporated into any of a myriad of larger and/or more complex systems, a representative example of which is system 700 shown schematically in FIG. 7. The system 700 can include a memory device 710, a power source 720, a driver 730, a processor 740, and/or other subsystems or components 750. The memory device 710 can include features generally similar to those of the apparatus described above with reference to one or more of the FIGS. and can therefore include various features for performing a direct read request from a host device. The resulting system 700 can perform any of a wide variety of functions, such as memory storage, data processing, and/or other suitable functions. Accordingly, representative systems 700 can include, without limitation, hand-held devices (e.g., mobile phones, tablets, digital readers, and digital audio players), computers, vehicles, appliances and other products. Components of the system 700 may be housed in a single unit or distributed over multiple, interconnected units (e.g., through a communications network). The components of the system 700 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to one or more of the FIGS. described above.

What is claimed is:

1. An apparatus comprising:
a printed circuit board (PCB);
circuit components mounted on a surface of the PCB, wherein the circuit components include a set of memory chips having a component height above the surface; and
thermally conductive posts attached to the PCB, the conductive posts extending away from the surface to a height at least equal to the component height, wherein the thermally conductive posts are thermally coupled to one or more of the circuit components for removing thermal energy away from the coupled one or more circuit components and dissipating the thermal energy out to surrounding environment.

2. The apparatus of claim 1, wherein the thermally conductive posts extend across a thickness of the PCB, the thermally conductive posts having bottom surfaces that are coincident with a bottom surface of the PCB.

3. The apparatus of claim 1, wherein the thermally conductive posts extend across a thickness of the PCB and protrude past a bottom surface of the PCB.

4. The apparatus of claim 1, further comprising:
a planar cover mounted at the height and directly to the thermally conductive posts.

5. The apparatus of claim 4, wherein the planar cover is a label.

6. The apparatus of claim 4, wherein the planar cover is a heat spreader.

7. The apparatus of claim 4, wherein a heat spreader is thermally connected to top portions of the set of memory chips.

8. The apparatus of claim 4, wherein:
the planar cover is an electromagnetic interference (EMI) shield; and
the thermally conductive posts include electrically conductive material and are electrically connected to the EMI shield.

9. The apparatus of claim 8, wherein the EMI shield and the thermally conductive posts are electrically coupled to an electrical ground.

10. The apparatus of claim 1, wherein:
the PCB includes (1) an inlet portion representative of a first end portion closer to a source for a coolant and (2) an outlet portion representative of a second end portion opposite the first end portion and farther from the source of the coolant; and
the thermally conductive posts are configured to disrupt a flow of the coolant from the inlet portion to the outlet portion for preventing a laminate flow of the coolant over the set of memory chips.

11. The apparatus of claim 10, wherein more of the thermally conductive posts are located closer to the inlet portion than the outlet portion.

12. The apparatus of claim 10, wherein one or more of the thermally conductive posts are located between a peripheral edge and a nearest one of the set of memory chips for disrupting the coolant before it flows over the set of memory chips.

13. The apparatus of claim 1, further comprising:
thermally-conductive paths on the PCB and thermally coupling the thermally conductive posts to the components, wherein the thermally-conductive paths are electrically disconnected from the components.

14. The apparatus of claim 1, wherein the circuit components include a Power Management Integrated Circuit (PMIC) configured to control a power supplied to the set of memory chips, wherein the PMIC is thermally coupled to one or more of the thermally conductive posts.

15. An in-line memory module comprising:
a printed circuit board (PCB);
circuit components mounted on a surface of the PCB, wherein the circuit components include a set of memory devices having a component height above the surface; and
thermally conductive posts attached to the PCB, the conductive posts extending away from the surface to a height at least equal to the component height, wherein the thermally conductive posts are thermally coupled to one or more of the circuit components for removing thermal energy away from the coupled one or more circuit components and dissipating the thermal energy out to surrounding environment.

16. The in-line memory module of claim 15, wherein the memory devices comprise Dynamic Random-Access Memory (DRAM) devices.

17. The in-line memory module of claim 15, wherein the in-line memory module comprises a Dual In-line Memory Module (DIMM).

18. The in-line memory module of claim 15, wherein the thermally conductive posts are further configured to disrupt air flow over the circuit components for increasing direct heat removal from the circuit components using the air flow.

19. A method of manufacturing a memory module, the method comprising:
obtaining a printed circuit board (PCB);
mounting circuit components mounted on a surface of the PCB, wherein the circuit components include a set of memory chips having a component height above the surface; and
attaching thermally conductive posts to the PCB, the conductive posts extending away from the surface to a height at least equal to the component height, wherein the thermally conductive posts are thermally coupled to one or more of the circuit components for removing thermal energy away from the coupled one or more circuit components and dissipating the thermal energy out to surrounding environment.

20. The method of claim 19, further comprising:
attaching a planar cover to the one or more thermally conductive posts and over the circuit components.
